(19) United States
(12) Patent Application Publication
(10) Pub. No.: US 2003/0073302 A1
(43) Pub. Date: Apr. 17, 2003

(54) Methods for formation of air gap interconnects

(75) Inventor: Andrew G. Huibers, Mountain View, CA (US)

Correspondence Address: REFLECTIVITY, INC., 350 POTRERO AVENUE, SUNNYVALE, CA, 94085, US

(73) Assignee: REFLECTIVITY, INC., a California corporation, Sunnyvale, CA

(21) Appl. No.: 10/270,465

(22) Filed: Oct. 11, 2002

Related U.S. Application Data
(60) Provisional application No. 60/329,385, filed on Oct. 12, 2001.

(51) Int. Cl. H01L 21/4763

(52) U.S. Cl. 438/622

(57) ABSTRACT

Processes are disclosed for forming integrated circuit devices where multilayered structures are formed having between layers a removable silicon material. The layers adjacent the removable silicon can be either conducting or insulating or both. After forming one or more layers with the removable silicon therebetween, the silicon is removed so as to provide for an air-gap dielectric. In one embodiment, adjacent layers are copper. Between the copper and removable silicon can be a barrier layer, such as a transition metal-silicon-nitride layer. In a preferred embodiment, the removable silicon is removed with a gas phase interhalogen or noble gas halide.

Related to the present application are U.S. Pat. No. 6,290,864 B1 issued Sep. 18, 2001 to Patel et al., and U.S. patent application Ser. No. 09/649,569 to Patel et al. filed Aug. 29, 2000; U.S. Ser. No. 60/293,092 to Patel et al. filed May 22, 2001; U.S. Ser. No. 09/954,864 to Patel et al. filed Sep. 17, 2001; and, U.S. Ser. No. 60/324,216 to Patel et al. filed Sep. 21, 2001, each of these being directed to various aspects of methods and apparatus for gas phase etching and are expressly incorporated herein by reference. Also relevant to the present invention is U.S. patent application Ser. No. 60/298,529 to Reid et al. filed Jun. 15, 2001 related to removal of organic materials with supercritical fluids and which is incorporated herein by reference.

Also relevant to the present invention are various US patents directed to air being the dielectric in a semiconductor device. Such patents include U.S. Pat. Nos. 6,228,770 to Pradeep et al., 6,057,224 to Bothra et al.; 6,171,971 to Natzle; 6,197,655 to Montanini et al.; 6,130,151 to Lin et al.; 6,287,979 to Zhou et al.; 6,268,261 to Petrarca et al.; 6,211,057 to Lin et al.; 6,071,805 to Liu et al.; 6,017,814 to Grill et al.; 5,814,555 to Bandyopadhyay et al.; 5,783,864 to Dawson et al.; 5,461,003 to Havemann et al.; 5,324,683 to Fitch et al.; 5,869,880 to Grill et al.; U.S. Pat. Nos. 5,559,055 to Chang et al.; 6,277,705 to Lee; 6,130151 to Lin et al.; 6,022,802 to Jang; 5,880,026 to Xing et al.; 5,759,913 to Fulford et al.; 5,708,303 to Jeng; 5,641,712 to Grivna et al.; 5,599,745 to Reinberg; 5,407,860 to Stoltz et al.; 5,310,700 to Lien et al.; 6,051,491 to Ito; 5,950,102 to Lee; 5,413,962 to Lur et al.; 5,227,658 to Beyer; 5,447,599 to Li et al.; 5,949,143 to Bang; 5,668,398 to Havemann; 6,300,667 to Miyamoto; 6,268,262 to Loboda; 6,211,561 to Zhao; 5,444,015 to Aitken et al.; 6,208,015 to Bandyopadhyay et al.; and 5,922,623 to Tsutsui, each of these patents incorporated herein by reference.

### TECHNICAL FIELD OF THE INVENTION

The invention relates to a method for fabricating semiconductor structures, and more particularly, to a method of forming a semiconductor device by removing material to form air-gaps for the dielectric in the device with particular gases for removing the material.

### DESCRIPTION OF THE PRIOR ART

The use of selective etchants to remove removable layers or regions in a multilayer structure without removal of an adjacent layer or region is a necessary and common step in the manufacture of semiconductor devices.

The success of an etch step in the manufacture of microstructures depends on a number of factors, prominent among which are the completeness and uniformity of the etch among the areas to be etched, both across and throughout the microstructure surface. For semiconductor devices, completeness and uniformity of the etch can be desirable to insure that features on all areas of the structure function fully and properly when in use. These factors are important in both isotropic and anisotropic etching. Isotropic etching is of particular interest, in structures where the purpose of the etch is to remove a removable layer that is intervening between functional layers or between a functional layer and a substrate. The bulk of the removable layer in these structures may be accessible to the etchant only through vias in the functional layer and etchant must proceed laterally outward from the vias. It is also desirable when forming semiconductor devices that functional materials that are not intended for removal, are not, in fact removed or damaged.

### SUMMARY OF THE INVENTION

The present invention provides improvements in the apparatus and methods used for the etching of layers or areas, in fabrication processes for multi-layered structures, e.g., an integrated circuit process. The process can be a standard MOS type process, a copper-damascene process, or any method for manufacturing semiconductor devices that has the need for dielectrics with low dielectric constant K between signal-carrying conductors. In one embodiment of the invention a method is provided where a sacrificial material is deposited in intervening areas.

The layers of the multi-layered structure could be conductive layers, conductive and dielectric layers, or even only dielectric layers. In any arrangement, the sacrificial material is removed by gas etch with a proper etchant, for example a noble gas halide or an interhalogen. In one aspect of the embodiment, the multi-layered structure is released and the intervening areas are filled with air (or gas or vacuum) after removal of the sacrificial material. Because air has extremely low dielectric constant κ compared to that of semiconductor materials, the dielectric constant κ values of the intervening areas are thus greatly reduced. In another aspect of the embodiment, intervening areas may be selectively re-filled with appropriate re-filling materials. For example, inert gases may be re-filled in intervening areas to protect the multi-layered structure. For another example, another dielectric material other than that of the sacrificial layer may be re-filled in the selected intervening areas to adjust the dielectric properties of the intervening areas, thus actively control the dielectric properties of the entire multi-layered structure. In another embodiment of the invention, the etchant is mixed with particular diluents (non-etching) gases (see U.S. Pat. No. 6,290,864 B1 issued Sep. 18, 2001 to Patel et al.). In yet another embodiment of the invention, the etchant gas is recirculated through the etching chamber (see U.S. patent application Ser. No. 09/649,569 to Patel et al. filed Aug. 29, 2000). In yet a further embodiment of the invention, an initial energized etch is used followed by a non-energized etch with an interhalogen or noble gas halide (see U.S. Ser. No. 60/293,092 to Patel et al. filed May 22, 2001). In an aspect of the embodiment of the invention, the etch is performed at a slow rate for improvements in the etch process (see U.S. Ser. No. 09/954,864 to Patel et al. filed Sep. 17,2001). And in a still further aspect of the invention the etch endpoint is determined based on the monitoring of the noble gas halide or interhalogen, or based on the monitoring of etching products (see U.S. Ser. No. 60/324,216 to Patel et al. filed Sep. 21, 2001).

The interhalogen or noble gas halide etchants for creating air gap dielectrics in the present invention are beneficial for their ability to not etch PECVD films and some metals in the way that an HF vapor etch harms these structures (as in the prior art). In addition, interhalogens and noble gas halides can etch silicon or silicon-containing material without leaving residue. The invention further comprises a passivation step that occurs after the etch, which could also involve a SAM (self-assembled mono-layer) material.

In addition, interhalogens and noble gas halides can beneficially remove silicon material via very small apertures, which small apertures allow deposition of further layers (after silicon removal) without the further layer material seeping through the apertures. For example, after removal of the silicon, the apertures can be closed off with a silicon compound (SiO2 or Si3N4) without the silicon compound material passing into the newly formed air gaps. The apertures can be as small as 0.15 microns or smaller.

### BRIEF DESCRIPTION OF THE DRAWINGS

While the appended claims set forth the features of the present invention with particularity, the invention, together with its objects and advantages, may be best understood from the following detailed description taken in conjunction with the accompanying drawings of which:

FIG. 1 is an illustration of the multi-layered device of the invention with air (or other dielectric materials) as the dielectric, with the air gaps being formed in accordance with the present invention;

FIG. 2 is a flow chart showing the steps executed in forming a multi-layered structure according to an embodiment of the invention; and

FIG. 3 is a flow chart showing the steps executed in forming a multi-layered structure according to another embodiment of the invention.

### DETAILED DESCRIPTION OF THE INVENTION AND PREFERRED EMBODIMENS

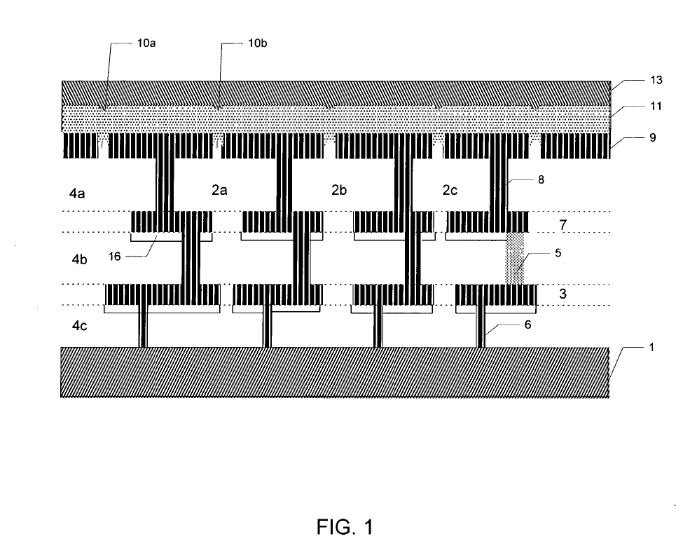

Referring to FIG. 1, a schematic diagram illustrating an exemplary multi-layered structure with air or other materials as the dielectric is presented therein. The multi-layered structure comprises patterned layers 3, 7, and 9. Neighboring patterned layers are connected via interconnects 6, 5, and 8. Additional layers 11 and 13 are deposited on the structure. The multi-layered structure as illustrated is built on top of substrate 1. The multi-layered structure of FIG. 1 is only one example and is not intended to suggest any limitation as to the scope of the invention. Neither should the number of layers comprised in the multi-layered structure be interpreted as only 9 (nine) layers, including the substrate layer 1, and the additional layers 11 and 13. Instead, a preferred “multi-layered structure” according to the present invention comprises more than 4 (four) layers including the substrate.

The substrate can be any suitable substrate, though preferably a semiconductor substrate (e.g., Si). Each layer of the multilayered structure can be conductive, semi-conductive or insulating. In general, the layers are patterned (e.g. by conventional photolithography) so as to form a multi-layered structure such as that illustrated in FIG. 1. Gaps patterned in the different layers can be filled, prior to deposition of the next layer, with sacrificial materials. The sizes of the gaps are generally very small with a typical value of 0.5 μm or less or even 0.3 μm or less. Exemplary sacrificial material is silicon or a material that is mostly composed of silicon (or a silicon layer is deposited first and patterned, followed by the conductive or insulating material). The multilayered structure could be any integrated circuit process that allows for one or more layers of silicon to be interconnected (fully encapsulated silicon islands can not be reached by the gas phase etchant). One possible process is a copper damascene process (e.g. dual damascene). In FIG. 1, a patterned layer 3 is followed by interconnects 5 (pillar 5 in FIG. 1 is insulating, whereas the other pillars in the layer are conducting). An additional layer 7 is a patterned conducting material, followed by conductive pillars 8 and a further patterned conductive layer 9. Any conductive layers or interlayer connections can be copper or aluminum or other electrically conductive materials, whereas any insulating layers or interconnections can be an oxide or nitride material (e.g. SiO2 or Si3N4) or other suitable electrically insulating materials. A sacrificial material(e.g., silicon) is presented in intervening areas (e.g. areas 2a, 2b, 2c) which is removed via apertures 10a, 10b prior to addition of further layers 11, 13 (e.g. PECVD SiN layers). A barrier or line 16 can insure the integrity of the structure both mechanically and by preventing diffusion or mixing of materials. The barrier or line can be located on the top, bottom or sidewalls of other structures, or any combination of these locations.

After removing sacrificial materials in intervening areas (e.g., 2a, 2b and 2c) and before depositing layer 11, appropriate dielectric materials can be re-filled in selected intervening areas for different purposes. For example, air can be re-filled in these intervening areas to reduce the dielectric constants of these areas, thus reducing the dielectric constant of the entire multi-layered structure. For another example, inert gases (e.g., Ar) can be re-filled into these intervening areas to protect the electronic or mechanic property of the multi-layered structure. As yet another example, intervening area can be selectively re-filled with selective dielectric materials to achieve a desired distribution of dielectric property, thereby the dielectric properties of the multi-layered structure can be actively controlled. For example, the sacrificial layers maybe suitable for use in the fabrication process for the interconnect stack—for example, a CMP-based samascene process, but can then be replaced by materials more suitable for device operations. The dielectric areas can also be under vacuum.

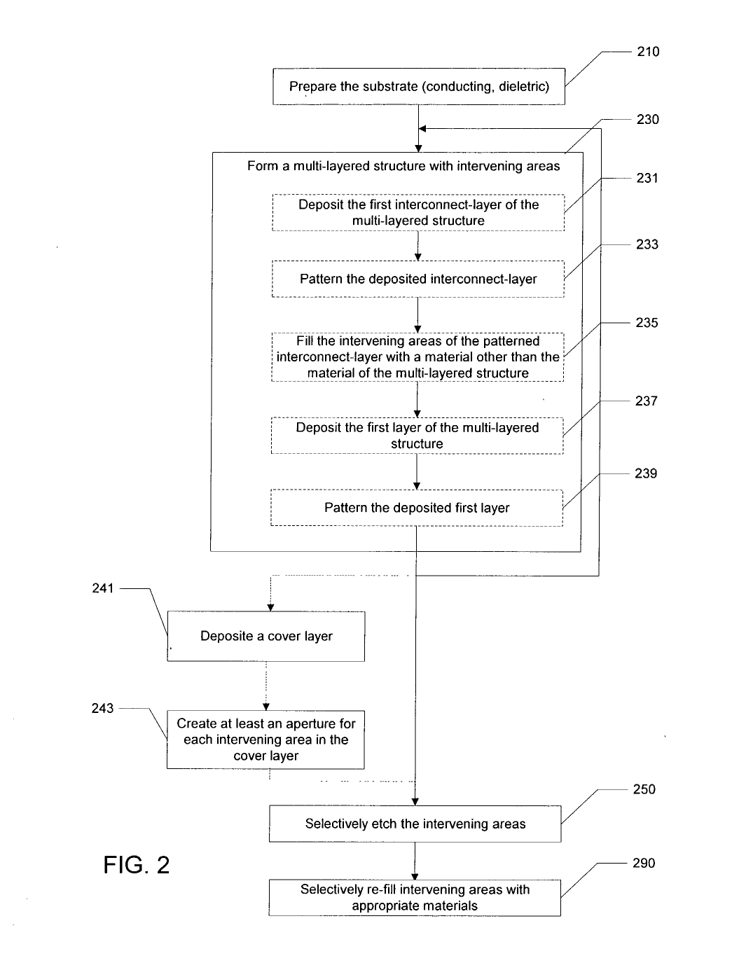

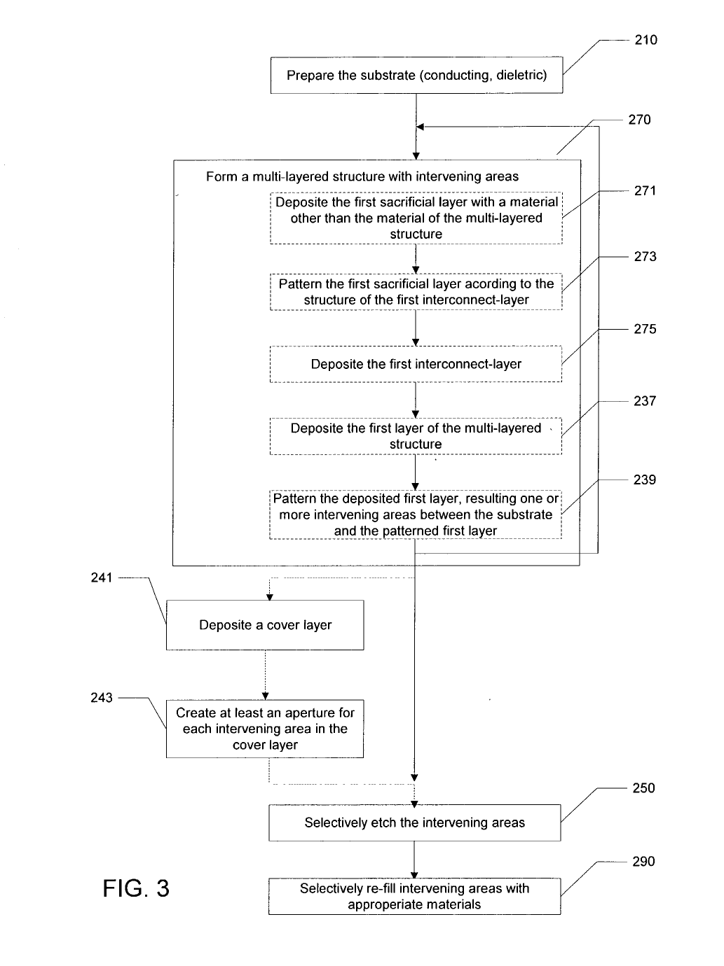

The multi-layered structure as presented in FIG. 1 can be fabricated in a variety of ways. Flow charts in FIGS. 2 and 3 demonstrate two exemplary ways. Referring to FIG. 2, a substrate (1 in FIG. 1) is prepared at step 210. The substrate can be conducting, insulating, or semi-conducting. On the substrate, a multi-layered structure with intervening areas as presented in FIG. 1 is then fabricated at step 230, wherein the intervening areas (e.g. 2a, 2b and 2c) are filled with sacrificial materials (e.g., a-Si). The fabrication process can be a standard MOS type process, a copper-damascene process, or any method for manufacturing semiconductor devices. Exemplary such processes will be further discussed in the following. In order to release the multi-layered structure, the intervening areas are selectively etched at step 250. After removing the intervening areas ((e.g., 2a, 2b and 2c in FIG. 1) at the etching step 250, appropriate dielectric materials can be re-filled in selected intervening areas for different purposes at step 290. For example, air can be re-filled in these intervening areas to reduce the dielectric properties of these areas, thus reduce the dielectric properties of the entire multi-layered structure. For another example, inert gases (e.g., Ar) can be re-filled into these intervening areas to protect the electronic or mechanic property of the multi-layered structure. As yet another example, intervening area can be selectively re-filled with selective dielectric materials to achieve a desired distribution of dielectric property, thereby the dielectric properties of the multi-layered structure can be actively controlled.

As an optional feature, additional layers can be deposited on the structure for varieties of purposes. As an example, but not a limitation, cover layer 11 is deposited for protecting the structure. This layer can be deposited before etching the inventing areas that is done at step 250. As shown in FIG.2, the cover layer is deposited at step 241 followed by step 243, wherein at least an aperture is created for each intervening area for etching the intervening area. The apertures can be as small as 0.15 μm or less. Alternatively (not shown in FIG. 2), the cover layer 11 can be deposited after the etching step or re-filling step 290 as appropriate. As another example, but not a limitation, layer 13 can also be deposited on the cover layer for enhancing the electronic or mechanical properties of the multi-layered structure. In such cases, the enhancing layer 13 is composed of Si3N4 or Cu.

The etch is accomplished with a proper etchant, for example a noble gas halide or an interhalogen. In an embodiment of the invention, the etchant is mixed with particular diluents (non-etching) gases (see U.S. Pat. No. 6,290,864 B1 issued Sep. 18, 2001 to Patel et al.). In yet another embodiment of the invention, the etchant gas is recirculated through the etching chamber (see U.S. patent application Ser. No. 09/649,569 to Patel et al. filed Aug. 29, 2000). In yet a further embodiment of the invention, an initial energized etch is used followed by a non-energized etch with an interhalogen or noble gas halide (see U.S. Ser. No. 60/293,092 to Patel et al. filed May 22, 2001). In an aspect of the embodiment of the invention, the etch is performed at a slow rate for improvements in the etch process (see U.S. Ser. No. 09/954,864 to Patel et al. filed Sep. 17,2001). And in a still further aspect of the invention the etch endpoint is determined based on the monitoring of the noble gas halide or interhalogen, or based on the monitoring of etching products (see U.S. Ser. No. 60/324,216 to Patel et al. filed Sep. 21, 2001).

The interhalogen or noble gas halide etchants for creating air gap dielectrics in the present invention are beneficial for their ability to not etch PECVD films and some metals in the way that an HF vapor etch harms these structures (as in the prior art). In addition, interhalogens and noble gas halides can etch silicon or silicon-containing material without leaving residue. The invention further comprises a passivation step that occurs after the etch, which could also involve a SAM (self-assembled mono-layer) material.

In addition, interhalogens and noble gas halides can beneficially remove silicon material via very small apertures, which small apertures (can be as small as 0.15 microns or less) allow deposition of further layers (after silicon removal) without the further layer material seeping through the apertures. For example, after removal of the silicon via apertures (e.g. 10a and 10b), the apertures can be closed off with a silicon compound (SiO2 or Si3N4 or other materials) without the silicon compound material passing into the newly formed air gaps.

In forming the multi-layered structure at step 230, further detailed operations are performed as illustrated in FIG. 2. With the substrate prepared at step 210, the first interconnect-layer (4c in FIG. 1) of the multi-layered structure is deposited at step 231. The interconnect-layer is then patterned into interconnects (6 in FIG. 1) at step 233. In order to build the next layer (e.g., layer 3 in FIG. 1) on top of the patterned interconnect-layer 4a, a sacrificial material is needed to fill the spaces left after patterning the interconnect-layer 4a. An exemplary such sacrificial material is silicon. This is done at step 235 followed by step 237, wherein the next layer (layer 3 in FIG. 1) is deposited. According to the designed structure, the deposited layer 3 in FIG. 1 is patterned at step 239. After the patterning, layer 3 in FIG. 1 opens multiple gaps as shown in FIG. 1. These steps are repeated until a layer without gap after patterning is to be deposited. Then the intervening areas (e.g., 2a, 2b and 2c in FIG. 1) filled with sacrificial materials are selectively etched at step 250.

In the above example, interconnecting-layers are deposited and patterned before depositing a sacrificial layer. Alternatively, sacrificial layers can be deposited before forming interconnecting-layer. Referring to FIG. 3, a multi-layered structure is formed (at step 270) on a substrate that is prepared at step 210. Different from that in step 230 in FIG. 2, a sacrificial layer is first deposited on the substrate at step 271 followed by step 273, wherein the sacrificial layer is patterned. On the patterned sacrificial layer, an interconnect-layer (e.g., 6 in FIG. 1) is deposited at step 275. Then a next layer of the multi-layer structure is deposited and patterned at steps 237 and 239, respectively. The fabrication process continues after all layers are grown.

Many variations relative to FIG. 1 are possible. Removable silicon material can be removed from areas within a single layer, only between layers, or both. It is possible to only remove silicon in some areas, while leaving it in other areas. Also, the silicon can be amorphous silicon in some areas of the device and polysilicon in other areas.

As a way of example, but not a limitation, applications of the embodiments of the present invention is discussed in the following with reference to a fabrication process of a multi-layered structure. For simplicity purpose, the structure comprises first and second layers selected from first and second conducting layers, first and second dielectric layers or a first dielectric and a second conducting layer, with silicon filling spaces between the layers and the first and second layers being made of a material other than silicon. The materials of the layers of the layered-structure can be silicon compound (e.g. silicon nitride or silicon dioxide), ceramic material, metal (e.g. copper) or metal alloy that comprise copper, tantalum, titanium or aluminum. The metal materials can be formed on the layers using standard ion implementation technique. As an optional feature, a barrier material/layer adjacent the first and/or second layers can also be deposited.

According to the invention, the multi-layered structure can be fabricated using standard MOS type process or damascene process. In either process, a sacrificial material is selected and deposited to assist the fabrication of the layered-structure. The sacrificial material can be amorphous silicon having a hydrogen concentration of 40% or less. Alternatively, a PECVD, LPCVD or sputtered amorphous silicon deposited in a glow discharge can also be selected as the sacrificial material. Typical sacrificial silicon has a long range order of 100 nm or less according to the invention. As an optional feature, the sacrificial silicon can be doped with boron, phosphorous or arsenic. The doping can be achieved using implantation at a rate of 10¹⁰ to 10¹⁴ ions/cm³, and an energy of 10 to 70 keV. At a time to release the multi-layered structure, the sacrificial material is removed using gas etch techniques.

In order to efficiently remove the sacrificial material from the layered-structure, etching parameters (etchants, etching pressure, etching selectivity, etching rate etc.) are carefully determined. For example, the silicon-based sacrificial material is etched with a gas phase etchant selected from interhalogens and noble gas halides, for example gas fluoride etchant. Moreover, the etchant gas can be selected from a group consisting of noble gas fluorides and halogen fluorides. The noble gas fluoride can be a member selected from a group consisting krypton difluoride, the xenon fluorides, xenon difluoride, xenon tetrafluoride, and xenon hexafluoride. The halogen fluoride can be a member selected from the group consisting of chlorine trifluoride, bromine trifluoride, and iodine pentafluoride. An improvement is that the etchant gas is utilized in a form of a gas mixture in which the etchant gas is mixed with a non-etchant gaseous additive (e.g. nitrogen, argon, helium, neon, and mixtures). The molar ratio can be from about 10:1 to about 200:1 or about 20:1 to about 150:1. Typical partial pressure of the etchant gas in the gas mixture is about 0.1 mbar, and the molar ratio of the non-etchant gaseous additive to the etchant gas can be from about 1:1 to about 500:1, such that the gas mixture achieves substantially greater etching selectivity toward the silicon portion than would be achieved with the etchant gas alone. molar ratio is from about 10:1 to about 200:1. Typically the non-etchant gaseous additive has a molar-averaged formula weight of less than about 25 (e.g. about 4 to 25, 4 to about 20 or 4 to 10). In general, the non-etchant gaseous additive has a molar-averaged thermal conductivity at 300 K and atmospheric pressure of from about 10 mW/(m K) to about 200 mW/(m K) or from about 140 mW/(m K) to about 190 mW/(m K).

The etching is performed at a pressure of from 0.5 to 760 Torr or 50 to 600 Torr, as appropriate. During etching, the selectivity toward a material (e.g. the materials of the layered-structure) other than silicon can be 2000:1 or more. Alternatively, the selectivity toward a material other than silicon can also be 10000:1 or more. The etching rate for etching the silicon sacrificial materials can be 7.2 um/hr or less. Alternatively, the silicon can also be etched at a rate of about 3 um/hr or less.

In general, the gas etching is performed in a chamber wherein the selected etchant in gas phase is provided and wherein the vapor phase etchant is capable of etching the multi-layered-structure with sacrificial materials in a non-energized state. In order to secure the etching quality, the etching process can be well controlled, which can be achieved by monitoring the gas in or from the etching chamber; and determining the end point of the etch based on the monitoring of the gas from the etching chamber. The end point can be determined in many ways For example, the end point can be determined based on a value of an etching product passing below a threshold. For another example, the derivative is taken of partial pressure values of an etching product and the end point can be determined when a derivative value is negative. The end point can also be determined the partial pressure of a gas component decreases for a predetermined period of time. Exemplary such silicon-compounds are silicon fluoride, SiF, SiF2, SiF3 and/or SiF4. As an optional feature, curve smoothing is performed prior to determining an end point of the etch.

It is also possible to use an organic material in place of the removable silicon material, and then remove the organic material with a supercritical fluid with or without a co-solvent. Various types of organic materials can be deposited and removed in this way, with additional details being set forth in co-assigned U.S. patent application Ser. No. 60/298,529 to Reid mentioned above and incorporate herein by reference.

The organic material of the sacrificial layer can be any suitable organic material, selected based on toxicity, type of solvent needed for dissolution, ease of handling, cost, etc. For example, the organic compound can be, or have a group in its molecule, selected from alkene, cyclic alkene and cyclic alkane, lactone, anhydride, amide, ketal, acetal, acid halide, halide, heterocycle, arene, ozonide, peroxide, epoxide, furan, lactam, aldehyde, detone, alcohol, nitro, hydroxylamine, nitrile, oxime, imine, azine, hydrazone, aniline, azide, ether, phenol, nitroso, azo, diazonium isothiocyanate, thiocyanate, cyanate, etc. Polymers can be used as the organic material—though the greater the cross linking the more likely that an organic solvent should be used as the supercritical fluid or as a cosolvent in the supercritical fluid. Preferred polymers are alkyds, acrylics, epoxies, fluorocarbons, phenolics, polyimides, polyurethanes, polyvinyls, polyxylylenes and silicones. Monomers, mixtures of monomers or monomers and polymers can also be used.

The sacrificial layer comprises an organic material, a carbon compound, that is deposited by, for example, spray-on or spin-coating. In one embodiment, the organic material is mixed with a solvent and deposited on a substrate. The solvent is preferably any known solvent for dissolving the organic material to be used, such as a supercritical fluid and/or a volatile organic solvent. The solvent is selected based on good handling, spinning and film forming properties (for spin on non-supercritical embodiments). In a preferred embodiment, a supercritical fluid, such as carbon dioxide, along with a cosolvent, dissolves a polymer and deposits the dissolved polymer on a substrate as a sacrificial layer.

In order to release the multi-layered structure, the organic sacrificial layer (or layers if multiple sacrificial layers are provided on the substrate) is removed with a supercritical fluid (or near-supercritical fluid). “Supercritical fluids” is the term used to describe those fluids that have been compressed beyond their critical pressure and also heated above their critical temperature. Both gases (e.g. carbon dioxide, nitrous oxide) and liquids (e.g. water) are suitable. More particularly, fluids that can be made into a supercritical fluid state for the present invention, include inorganic gases and organic gases, such as nitrogen, alkanes and preferably lower alkanes (e.g. methane, ethane, propane, butane), or alkenes, preferably lower alkenes (e.g. propylene). Also usable in the present invention are supercritical xenon, krypton, methanol, ethanol, isopropanol and isobutanol. Supercritical hydrocarbons or fluorocarbons could also be used, as well as partially fluorinated and perfluorinated halocarbons, and highly polar hydrogen bonding solvents. Other examples of supercritical fluids that could be used in the present invention include supercritical ethanol, acetic acid, xenon and ethane, and mixtures thereof.

More than one supercritical fluid can be used (as a mixture), and one or more cosolvents (discussed below) can also be used with the mixture of supercritical fluids. Various supercritical fluids and their critical temperatures and pressures are set forth on pages F-64 to F-66 in CRC Handbook of Chemistry and Physics, 68th Edition, 1987-1988 (these pages incorporated herein by reference). Near supercritical fluids also demonstrate solubility, viscosity, density, and behavior characteristics similar to supercritical fluids, and can be used, as can subcritical fluids (herein defined as a fluid below its critical temperature but above its critical pressure or vice versa), depending upon the fluid, whether there is an additional solvent, and the nature of the organic material being removed.

Solvents (used in their supercritical state or as a cosolvent with a supercritical fluid) can be selected based on their known ability for dissolving the organic material to be removed (or deposited or patterned). One approach that is used is to divide the Hildebrand's total solubility parameter into secondary intermolecular forces—dispersion, dipole-dipole and hydrogen bonding. When plotted in a three dimensional Cartesian coordinate system, each solvent and polymer can be represented by a “region” (see Barton, Allan, Handbook of Solubility Parameters and Other Cohesion Parameters, CRC Press, Inc., p.8 and p.141). Some obvious solvent candidates are those that have known solubility of particular photoresist materials, such as amyl acetate, butoxyethanol, gamma butyrolactone, cyclohexanone, dichlorobenzene, ethyl lactate, heptanone, mineral spirits, mesitylene, methyl cellusolve acetate, methyl isobutyl ketone, n-methyl pyrolidinone, propylene glycol monomethyl ether acetate, and xylene.

The phase behavior or ternary systems of carbon dioxide and the solubilities of a large number of compounds in liquid carbon dioxide and supercritical carbon dioxide have been much studied since 1954. Carbon dioxide is not a very good solvent for high molecular weight and polar compounds (with some exceptions as noted previously). To increase the solubility of such compounds in liquid or supercritical carbon dioxide (and subcritical and near supercritical carbon dioxide), small amounts (e.g. less than 50 mol %, preferably from 0 to 25% mol %) of polar or non-polar cosolvents can be added. These cosolvents can be used themselves as the supercritical fluid, however, more environmentally friendly substances such as water, carbon dioxide and nitrous oxide are preferred as the supercritical fluid, with the cosolvent used being a minor mol %. Cosolvents such as methane, ethane, propane, butane, etc., and methanol, ethanol, propanol, butanol, etc., as well as methylene, ethylene, propylene, butylene, etc., as well as lower hazard organic co-solvents such as methylene carbonate, ethylene carbonate, propylene carbonate, etc. as well as the chlorides of methylene, ethylene, propylene, etc. can be used. Other possible cosolvents include hexanoic acid, octanoic acid, decanoic acid, pentanoic acid, heptanoic acid, furfural, trioctylamine, isopropylamine, trioctylphosphine oxide, 2-ethyl hexanol, n-butanol, n-amyl alcohol, t-amyl alcohol, decyl alcohol, and mixtures thereof.

Many other solvents can be used for both depositing the organic sacrificial layer and removing the organic sacrificial layer (as a supercritical fluid or preferably mixed with a supercritical fluid such as carbon dioxide, water, or nitrous oxide. Examples include ethyl acetate, propionitrile, toluene, xylene, tetramethylene sulfone, cellosolve acetate. More particularly, suitable solvents which may be utilized include ketones such as acetone, methyl ethyl ketone, methyl isobutyl ketone, mesityl oxide, methyl amyl ketone, cyclohexanone and other aliphatic ketones; esters such as methyl acetate, ethyl acetate, alkyl polycarboxylic acid esters; ethers such as methyl t-butyl ether, dibutyl ether, methyl phenyl ether and other aliphatic or alkyl aromatic ethers; glycol ethers such as ethoxy ethanol, butoxy ethanol, ethoxy 2-propanol, propoxy ethanol, butoxy propanol and other glycol ethers; glycol ether esters such as butoxy ethoxy acetate, ethyl 3-ethoxy propionate and other glycol ether esters; alcohols such as methanol, ethanol, propanol, isopropanol, butanol, iso-butanol, amyl alcohol and other aliphatic alcohols; aromatic hydrocarbons such as toluene, xylene, and other aromatics or mixtures of aromatic solvents; aliphatic hydrocarbons such as VM&P naphtha and mineral spirits, and other aliphatics or mixtures of aliphatics; nitro alkanes such as 2-nitropropane. A review of the structural relationships important to the choice of solvent or solvent blend is given by Dileep et al., Ind. Eng. Chem. (Product Research and Development) 24, p. 162 (1985) and Francis, A. W., J. Phys. Chem. 58, p. 1099 (1954).

The invention has been described in terms of specific embodiments. Nevertheless, persons familiar with the filed will appreciate that many variations exist in light of the embodiments described herein.

What is claimed is:

1. A method of forming an integrated circuit, comprising:
a) forming a layered structure including at least first and second layers selected from first and second conducting layers, first and second dielectric layers or a first dielectric and a second conducting layer, with silicon filling spaces between the layers and the first and second layers being made of a material other than silicon; and
b) etching the layered structure with a gas phase etchant selected from interhalogens and noble gas halides so as to remove the silicon and form a gap between the first and second layers and decrease the k value in the gap.

2. The method of claim 1, wherein the silicon is etched at a rate of 7.2 um/hr or less.

3. The method of claim 2, wherein the silicon is etched at a rate of about 3 um/hr or less.

4. The method of claim 1, wherein the silicon is amorphous silicon having a hydrogen concentration of 40 at % or less.

5. The method of claim 1, wherein the silicon is PECVD amorphous silicon deposited in a glow discharge.

6. The method of claim 1, wherein the etching of the silicon material is at a pressure of from 0.5 to 760 Torr.

7. The method of claim 6, wherein the etching of the silicon material is at a pressure of from 50 to 600 Torr.

8. The method of claim 1, wherein the selectivity toward a material other than silicon is 2000:1 or more.

9. The method of claim 2, wherein the selectivity toward a material other than silicon is 10000:1 or more.

10. The method of claim 1, wherein the silicon is preferentially etched relative to an adjacent metal in the first and/or second layer.

11. The method of claim 10, wherein the material other than silicon is a silicon compound.

12. The method of claim 11, wherein the silicon compound is silicon nitride or silicon dioxide.

13. The method of claim 11, wherein the material other than silicon is a ceramic material.

14. The method of claim 1, wherein the material other than silicon is a metal.

15. The method of claim 14, wherein the metal or metal alloy comprises copper, tantalum, titanium or aluminum.

16. The method of claim 15, wherein the metal is copper.

17. The method of claim 15, which is a damascene process.

18. The method of claim 1, wherein the silicon is PECVD, LPCVD or sputtered silicon.

19. The method of claim 1, wherein the silicon has a long range order of 100 nm or less.

20. The method of claim 16, wherein the ion implantation is performed on the silicon after deposition.

21. The method of claim 1, wherein prior to etching the silicon material:
depositing the silicon material on a substrate; and
depositing the adjacent first and second layers before or after depositing the silicon.

22. The method of claim 21, wherein a semiconductor device is formed.

23. The method of claim 1, further comprising depositing a barrier material adjacent the first and/or second layers.

24. The method of claim 21, wherein the first layer comprises a metal and the second layer comprises a dielectric.

25. The method of claim 21, wherein the first and second layers comprise dielectric materials.

26. The method of claim 21, wherein a plurality of layers other than silicon are deposited on the silicon material.

27. The method of claim 1, wherein the silicon is polysilicon.

28. The method of claim 1, wherein the gas phase etchant is provided to a chamber in which the sample comprising silicon is disposed, and wherein the vapor phase etchant is capable of etching the sample in a non-energized state, and further comprising:
monitoring the gas in or from the etching chamber; and
determining the end point of the etch based on the monitoring of the gas from the etching chamber.

29. The method of claim 28, wherein an end point is determined based on a value of an etching product passing below a threshold.

30. The method of claim 28, wherein a derivative is taken of partial pressure values of an etching product.

31. The method of claim 30, wherein an end point is determined when a derivative value is negative.

32. The method of claim 28, wherein an end point is determined when a partial pressure of a gas component decreases for a predetermined period of time.

33. The method of claim 28, wherein curve smoothing is performed prior to determining an end point of the etch.

34. The method of claim 28, wherein the material is silicon and the etchant is a gas fluoride etchant.

35. The method of claim 34, wherein the etch product that is monitored is a silicon fluoride compound.

36. The method of claim 35, wherein the etch product that is monitored is SiF, SiF2, SiF3 and/or SiF4.

37. The method of claim 1, wherein the silicon is doped during deposition.

38. The method of claim 37, wherein the silicon is doped with boron, phosphorous or arsenic.

39. The method of claim 38, wherein the doping is achieved by implantation at 10¹⁰ to 10¹⁴ ions/cm³.

40. The method of claim 39, wherein the doping is performed at an energy of 10 to 70 keV.

41. The method of claim 1, the silicon material is part of a silicon portion that is etched relative to a non-silicon portion of the sample, said non-silicon portion consisting of a member selected from the group consisting of a non-silicon metal, a compound of a non-silicon metal, and a silicon-containing compound in which silicon is bonded to a non-silicon element, by exposing both said silicon portion and said non-silicon portion to an etchant gas selected from the group consisting of noble gas fluorides and halogen fluorides, the improvement in which said etchant gas is utilized in the form of a gas mixture in which said etchant gas is mixed with a non-etchant gaseous additive, the partial pressure of said etchant gas in said gas mixture being at least about 0.1 mbar, and the molar ratio of said non-etchant gaseous additive to said etchant gas being from about 1:1 to about 500:1, such that said gas mixture achieves substantially greater etching selectivity toward said silicon portion than would be achieved with said etchant gas alone.

42. The method in accordance with claim 41 in which said non-etchant gaseous additive has a molar-averaged formula weight of less than about 25.

43. A method in accordance with claim 41 in which said non-etchant gaseous additive has a molar-averaged formula weight of from about 4 to about 25.

44. A method in accordance with claim 41 in which said non-etchant gaseous additive has a molar-averaged formula weight of from about 4 to about 20.

45. A method in accordance with claim 41 in which said non-etchant gaseous additive has a molar-averaged formula weight of from about 4 to about 10.

46. A method in accordance with claim 41 in which said non-etchant gaseous additive has a molar-averaged thermal conductivity at 300 K and atmospheric pressure of from about 10 mW/(m K) to about 200 mW/(m K).

47. A method in accordance with claim 41 in which said non-etchant gaseous additive has a molar-averaged thermal conductivity at 300 K and atmospheric pressure of from about 140 mW/(m K) to about 190 mW/(m K).

48. A method in accordance with claim 41 in which said molar ratio is from about 10:1 to about 200:1.

49. A method in accordance with claim 41 in which said molar ratio is from about 20:1 to about 150:1.

50. A method in accordance with claim 41 in which said non-etchant gaseous additive is a member selected from the group consisting of nitrogen, argon, helium, neon, and mixtures thereof.

51. A method in accordance with claim 41 in which said non-etchant gaseous additive is a member selected from the group consisting of helium, neon, mixtures of helium and neon, and mixtures of one or both of helium and neon with one or both of nitrogen and argon.

52. A method in accordance with claim 41 in which said non-etchant gaseous additive is a member selected from the group consisting of helium, a mixture of helium and nitrogen, and a mixture of helium and argon.

53. A method in accordance with claim 41 in which said non-etchant gaseous additive is a member selected from the group consisting of helium and a mixture of helium and nitrogen.

54. A method in accordance with claim 41 in which said non-etchant gaseous additive is helium.

55. A method in accordance with claim 41 in which said etchant gas is a noble gas fluoride.

56. A method in accordance with claim 55 in which said noble gas fluoride is a member selected from the group consisting of krypton difluoride and the xenon fluorides.

57. A method in accordance with claim 55 in which said noble gas fluoride is a member selected from the group consisting of xenon difluoride, xenon tetrafluoride, and xenon hexafluoride.

58. A method in accordance with claim 55 in which said noble gas fluoride is xenon difluoride.

59. A method in accordance with claim 55 in which said noble gas fluoride is xenon difluoride and said non-etchant gaseous additive is a member selected from the group consisting of helium, neon, and mixtures one or more or helium and neon with one or more of nitrogen and argon.

60. A method in accordance with claim 55 in which said noble gas fluoride is xenon difluoride and said non-etchant gaseous additive is a member selected from the group consisting of helium and a mixture of nitrogen and helium.

61. A method in accordance with claim 41 in which said etchant gas is a halogen fluoride.

62. A method in accordance with claim 61 in which said halogen fluoride is a member selected from the group consisting of chlorine trifluoride, bromine trifluoride, and iodine pentafluoride.

63. A method in accordance with claim 61 in which said halogen fluoride is a member selected from the group consisting of chlorine trifluoride and bromine trifluoride.

64. A method in accordance with claim 61 in which said halogen fluoride is bromine trifluoride.

65. A method in accordance with claim 41 in which the partial pressure of said etchant gas is from about 0.3 mbar to about 30 mbar.

66. A method, comprising:
a) forming a layered structure that includes a first conductive layer and either a dielectric layer or a second conductive layer, with silicon filling spaces between the conductive layer and the dielectric or second conductive layer;
b) etching the layered structure with an etchant gas comprising an interhalogens or a noble gas halides so as to remove the silicon and form a gap between the first conductive layer and the dielectric or second conductive layer.

67. The method of claim 66, further comprising:
(a) placing said sample in an etching chamber disposed within a gas recirculation loop, said etching chamber in communication with a source of etchant gas, and said gas recirculation loop having a pump disposed therein;
(b) passing etchant gas from said source of etchant gas into said etching chamber to expose said sample to said etchant gas; and
(c) recirculating said etchant gas through said recirculation loop by way of said pump.

68. The method of claim 67 further comprising passing said etchant gas through an expansion chamber prior to step (b) and, while said etchant gas is in said expansion chamber, forming a mixture of said etchant gas with non-etchant gases, and step (b) comprises passing said etchant gas as part of said mixture into said etching chamber.

69. The method of claim 67, wherrein said pump is a continuous recirculation pump and step (c) comprises continuously recirculating said etchant gas through said recirculation loop.

70. The method of claim 67, further comprising bleeding etchant gas into said recirculation loop during step (c).

71. The method of claim 66, wherein the etchant gas is a gas mixture which further comprises a non-etchant gas additive at a partial pressure and a molar ratio relative to said fluoride gas such that said gas mixture achieves greater etching selectivity toward said silicon portion than would be achieved with said fluoride gas alone.

72. The method of claim 71, wherein said non-etchant gas additive is a member selected from the group consisting of nitrogen, argon, helium, neon, and mixtures thereof.

73. The method of claim 72, wherein the non-etchant gas additive is a member selected from the group consisting of helium, a mixture of helium and nitrogen, and a mixture of helium and argon.

74. The method of claim 73, wherein the gas phase etchant comprises xenon difluoride or bromine trifluoride and the non-etchant gas additive comprises helium.

75. A process for manufacturing a microprocessor, the process comprising:
a) creating a plurality of adjacent structures having a silicon fill between the adjacent structures;
b) creating at least one layer above the adjacent structures and the fill;
c) creating at least one discrete pathway to said fill through said layer; and
d) converting said silicon fill to a gas product with a gas phase interhalogen or noble gas halide which gas product escapes through the pathway leaving an air void between the adjacent structures.

76. The process of claim 75, wherein the silicon fill comprises amorphous silicon.

77. The process of claim 75, wherein step (a) comprises creating a plurality of conductive lines.

78. The process of claim 77, wherein step (a) comprises creating a plurality of conductive lines surrounded by a barrier layer.

79. The process of claim 78, wherein the barrier layer comprises an early transition metal-silicon-nitride.

80. A method for forming air gaps between metal leads of a semiconductor device, comprising the steps of:
depositing a metal layer on a substrate;
etching said metal layer in a pattern to form metal leads, said metal leads having tops;
depositing a removable silicon layer between said metal leads;
depositing a porous dielectric layer over said removable silicon layer and said metal leads; and
removing said removable silicon layer through said porous dielectric layer with a gas phase interhalogen or noble gas halide so as to form air gaps between said metal leads beneath said porous dielectric layer.

81. A method of fabricating a multi-layered structure, the structure having a set of alternating layers selected from layers of semiconductor, conductor and insulator, wherein the neighboring layers are connected via a plurality of interconnects, and wherein the layers and the interconnects surround a multiplicity of intervening areas, the method comprising:
forming the multi-layered structure with a sacrificial material filled the intervening areas; and
selectively etching the intervening areas for removing the sacrificial layer using with a gas phase interhalogen or noble gas halide.

82. The method of claim 81, after the step of etching the intervening areas, further comprising:
re-filling the intervening areas using a selected re-filling material.

83. The method of claim 82, wherein the re-filling material is an inert gas.

84. The method of claim 81, after the step of etching the intervening areas, further comprising:
selecting one or more intervening areas;
selecting a re-filling material with an appropriate dielectric constant; and
filling the selected intervening areas with the selected re-filling materials.

85. A method of forming an integrated circuit, comprising:
forming a layered structure including at least first and second layers selected from first and second conducting layers, first and second dielectric layers or a first dielectric and a second conducting layer, with silicon filling spaces between the layers and the first and second layers being made of a material other than silicon; and
etching the layered structure with a gas phase etchant that is a supercritical fluid so as to remove the organic material and form a gap between the first and second layers and decrease the k value in the gap.

86. A method of fabricating a multi-layered structure, the structure having a set of alternating layers selected from layers of semiconductor, conductor and insulator, wherein the neighboring layers are connected via a plurality of interconnects, and wherein the layers and the interconnects surround a multiplicity of intervening areas, the method comprising:
forming the multi-layered structure with a sacrificial material filled the intervening areas; and
selectively etching the intervening areas for removing the sacrificial layer using with a gas phase supercritical fluid
